(19) United States
(12) Patent Application Publication
(10) Pub. No.: US 2006/0109014 A1
(43) Pub. Date: May 25, 2006

(54) Test pad and probe card for wafer acceptance testing and other applications

(76) Inventors: Te-Tsung Chao, Koahsiung (TW); Chao-Yuan Su, Koahsiung City (TW); Pei-Haw Tsao, Taichung (TW); Chender Huang, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/996,242

(22) Filed: Nov. 23, 2004

(51) Int. Cl. G01R 31/02

(52) U.S. Cl. 324/754

(57) ABSTRACT

A probe card having a member for sending and receiving electrical signals for operational testing of a semiconductor integrated circuit, and a plurality of probe pins extending from the member in a manner which causes free ends of the pins to contact wafer test pads substantially across a maximum dimension of the pads. Also, a test pad for a wafer or a substrate having a pad of electrically conductive material disposed in an area between seal rings of the wafer or substrate, the pad having a shape and/or a rotational orientation within the area between the seal rings that minimizes pad material immediately adjacent the seal rings. Further, a test pad for a wafer or substrate including a passivation layer disposed thereover, the test pad formed of a layer of electrically conductive material and disposed in an opening in the passivation layer, the opening disposed over an uppermost metal layer of the wafer or substrate, the opening and the test pad dimensioned so that the test pad does not contact the passivation layer. Still further, a protection structure for a wafer die core comprising a wafer including a passivation layer and a test pad extending through the passivation layer, and a trench in the passivation layer adjacent to an edge of the test pad.

### FIELD OF THE INVENTION

The invention relates to semiconductor integrated circuit testing and adjustment. More particularly, the invention relates to improvements in test pads and probe cards for performing wafer acceptance testing.

### BACKGROUND

Semiconductor wafers and other substrates are usually tested for defects using a wafer acceptance testing (WAT) method. In the WAT method, one or more test pads are typically formed on scribe lines between adjacent wafer dies to be tested.

A probe card is used to test the electrical operation of the multiple circuit devices in the semiconductor wafer. The probe card includes a plurality of probe pins which are brought into contact with the test or WAT pads of the wafer. After testing, the wafer is diced to separate the wafer dies from one another by sawing along the scribe lines.

As is well known in the art, seal rings are provided in most silicon chip designs to prohibit die core cracking and/or to stop mobile ions or moisture from penetrating into microelectronic devices fabricated in the core logic circuit area during die assembly or during operation in the field. The seal rings accomplish this by surrounding and isolating the core of each die. A problem associated with the test pads is that after dicing, residual test pad material remains in front of the seal rings. This residual test pad material often causes pad peel-back, i.e., the peel-back of the residual test pad material toward the seal rings. As the residual test pad material peels, cracks originate under the test pad remnant and propagate toward the core of the wafer die where the active devices are located. Such cracking causes reliability concerns, as the cracking can damage the die core, causing current leakage, etc.

One method of correcting the peel-back problem is to reduce the area of the test pads so that less test pad residue remains after dicing. However, as the area of the test pad is reduced, it becomes more difficult to properly engage or contact the probe pins of the probe card to the test pads.

Accordingly, solutions are needed which correct the peel-back and probe pin contact problems.

### BRIEF DESCRIPTION OF THE DRAWINGS

FIG. 1A is a plan view of a conventional test pad.

FIG. 1B is a plan view of the conventional test pad after dicing.

FIG. 1C is a cross-sectional view of the conventional test pad.

FIG. 2A is a plan view of a first embodiment of the test pad of the invention.

FIG. 2B is a plan view of the test pad of FIG. 2A after dicing.

FIG. 3A is a plan view of a second embodiment of the test pad of the invention.

FIG. 3B is a plan view of a third embodiment of the test pad of the invention.

FIG. 4 is a plan view of a fourth embodiment of the test pad of the invention.

FIG. 5 is a cross-sectional view of fifth embodiment of the test pad of the invention.

FIG. 6A is a cross-sectional view of first and second embodiments of the protection structure of the invention.

FIG. 6B is a plan view of the protection structures of the invention.

FIG. 7A is an elevational view of an embodiment of a probe card of the invention.

FIG. 7B is a plan view of the probe card of FIG. 7B.

FIG. 8A is a plan view showing how the probe pins extend from the substrate to contact the test pads of a wafer.

FIG. 8B is a plan view of probe pin marks made on the test pads by the probe card of the invention.

FIG. 9A is a plan view showing how a prior art probe pin extends to contact the test pad of a wafer.

FIG. 9B is a plan view of a probe pin mark made on the test pad by a prior art probe card.

It should be noted that like elements in the drawings are identified by like reference numerals.

### DETAILED DESCRIPTION

An aspect of the invention is a test pad for wafer acceptance testing (WAT) and other applications. In some embodiments, the test pad may be made from a metal, such as aluminum, or other electrically conductive material. In other embodiments, the test pad may be made from a non-electrically conductive material. In some embodiments, the test pad may be used within a scribe line between adjacent wafer dies. In other embodiments, the test pad may be used in other areas of the wafer.

The test pad has a shape and/or an orientation within the scribe line between seal rings of adjacent wafer dies or substrates, that substantially reduces the amount of pad material that is immediately adjacent or in front of the seal rings. Reducing the amount of test pad material in front of the seal rings substantially reduces the amount of test pad residue that remains in front of the seal rings after wafer dicing. This, in turn, substantially limits pad peel-back and the cracks associated therewith that propagate unfettered by the seal rings to the core of the wafer die where the microelectronic devices are located, after wafer dicing. Such cracking causes reliability concerns as the cracking can damage the die core, cause current leakage etc.

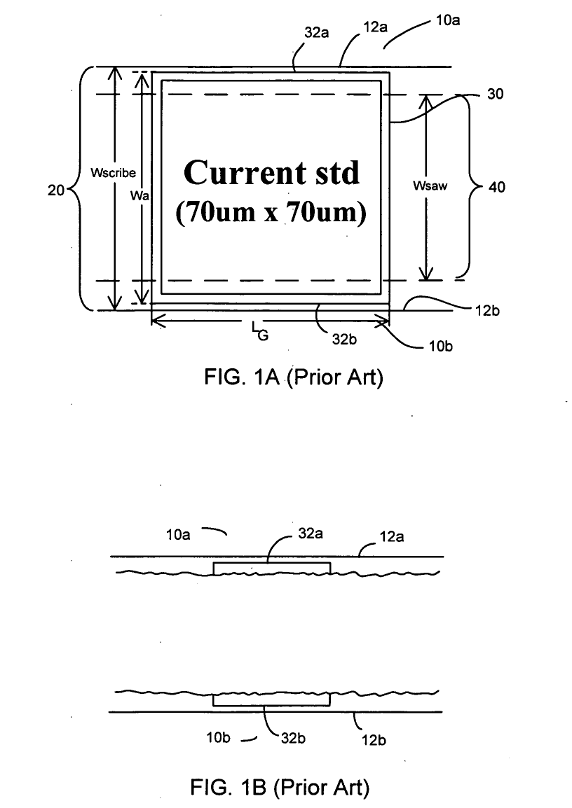

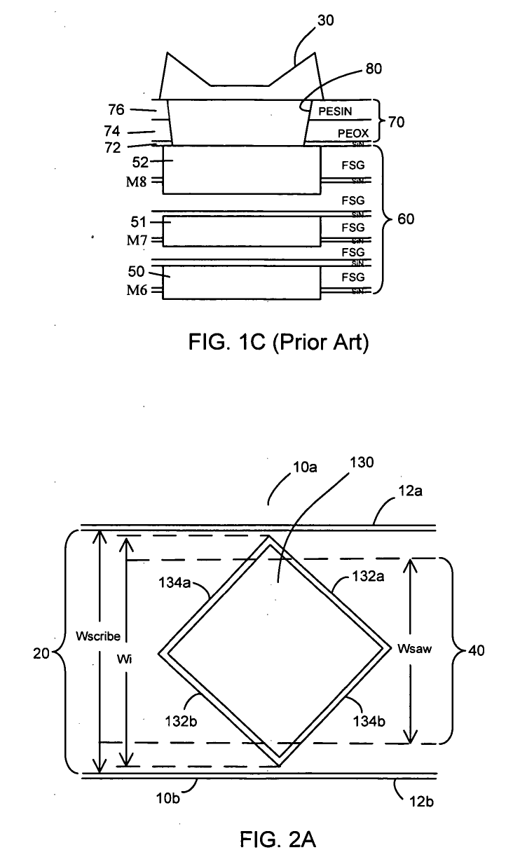

Referring now to the drawings and initially to FIG. 1A, there is shown a plan view of a conventional square shape test pad 30. The test pad 30 is disposed in a scribe line 20 between a first seal ring 12a of a first wafer die 10a and a second seal ring 12b of a second wafer die 10b, that extends parallel to the first seal ring 12a of the first wafer die 10a. For illustrative purposes only, the scribe line 20 may have a width W_{scribe} of about 72 um, and the test pad may have a length L₀ of about 70 um and a side-to-side width W₀ of about 70 um. The test pad 30 is conventionally oriented within the 72 um wide scribe line such that opposing edges 32a and 32b of the pad 30 are aligned and parallel with the first and second seal rings 12a and 12b. The shape and orientation of the conventional test pad 30 maximizes the amount of pad material that is disposed in front of each seal ring 12a and 12b.

The first and second dies 10a and 10b are separated from one another by sawing along the scribe line 20. The dicing process produces a saw line 40 having a width W_{saw} which is less than width W₀ of the test pad 30. As a result, a significant amount of test pad residue remains in front of each seal ring 12a and 12b as shown in FIG. 1B, thereby maximizing the probability of pad peel-back, which produces cracks that often propagate to the core of the wafer die where the active devices are located.

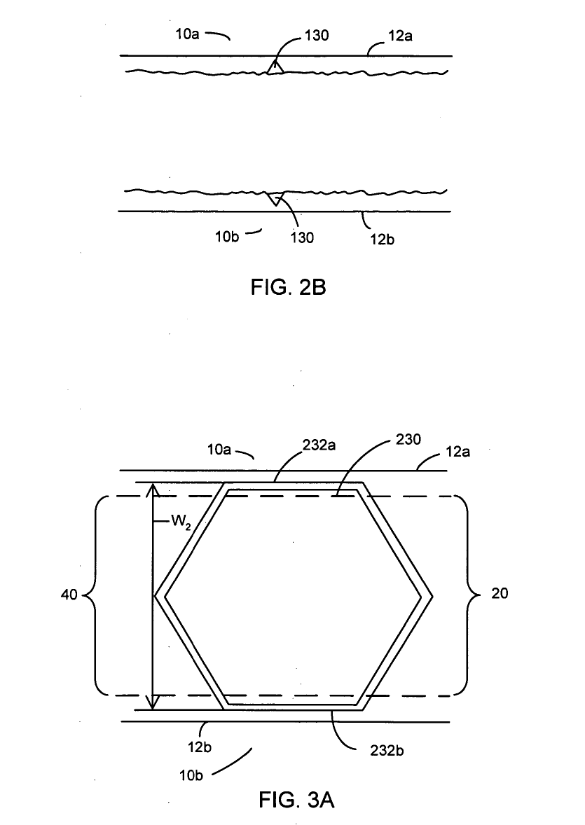

Referring now to FIG. 2A, there is shown a plan view of a first embodiment of the test pad 130 of the invention. The test pad 130 of the first embodiment may have a square shape similar to that of the conventional test pad 30 shown in FIG. 1A. The test pad 130 is rotated from the orientation of the conventional test pad 30 shown in FIG. 1A such that opposing edges 132a, 132b, 134a, 134b of the test pad 130 are not aligned and parallel with the first and second seal rings 12a and 12b. In the shown embodiment, the test pad 130 may be rotated approximately 45 degrees from the orientation of the conventional test 30 shown in FIG. 1A. The area of the test pad 130 may have to be reduced, relative to the conventional test pad 30 of FIG. 1A, to orient it in the same illustrative 72 um wide scribe line 20 when rotated 45 degrees. Assuming a 72 um wide scribe line, the test pad 130 may have a corner-to-corner width W₁ of about 70 um when rotated 45 degrees from the orientation shown in FIG. 1A.

When the first and second die 10a,10b are separated by sawing along the scribe line 20, the rotated test pad 130 of the first embodiment is more completely removed, thus reducing the amount of test pad residue remaining in front of the seal ring 12a, 12b of each die 10a, 10b as shown in FIG. 2B. Therefore, the probability of pad peel-back and the cracking associated therewith is reduced.

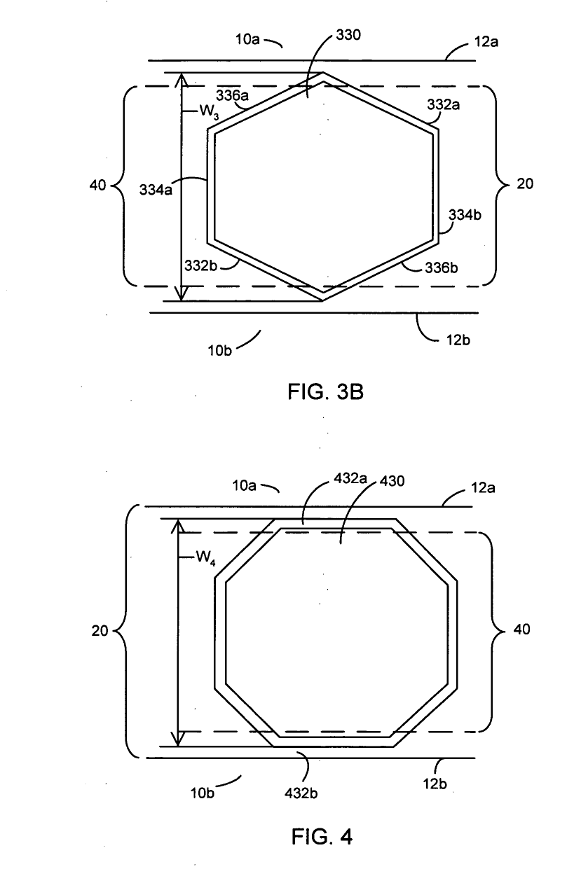

FIGS. 3A and 3B show plan views of second and third embodiments of the test pad 230 and 330 of the invention. In the second and third embodiments, the shape of the test pad has been modified, e.g., made hexagonal, to substantially reduce the amount of pad material that is immediately adjacent or in front of the seal rings 12a and 12b.

The hexagonal test pad 230 of the embodiment of FIG. 3A may be oriented within the illustrative 72 um wide scribe line such that opposing edges 232a and 232b of the pad 230 are aligned and parallel with the first and second seal rings 12a and 12b. In this illustrative embodiment (assuming a 72 um wide scribe line) the test pad 230 may have a side-to-side width W₂ of 70 um. The opposing edges 232a and 232b of the hexagonal shape test pad 230 are shorter in length than the opposing edges 32a and 32b of the conventional pad 30 of FIG. 1A, when their widths W₂ and W₀ are the same. Thus after dicing, a reduced amount of test pad residue remains in front of the seal ring 12a, 12b of each die 10a, 10b, which in turn, reduces the probability of pad peel-back and the die core cracking and damage associated therewith.

The hexagonal test pad 330 of the embodiment of FIG. 3B may be rotated, e.g., approximately 45 degrees, from the orientation of the hexagonal test pad 230 of FIG. 3A, such that opposing edges 332a, 332b, 334a, 334b, 336a, 336b of the pad 330 are not aligned to and parallel with the first and second seal rings 12a and 12b. In this illustrative embodiment (assuming a 72 um wide scribe line) the test pad 330 may have a corner-to-corner width W₃ of 70 um. The area of the test pad 330 is reduced relative to the test pad 230 of FIG. 3A to position it in the same illustrative 72 um wide scribe line 20 between the first and second seal rings 12a and 12b. When the first and second die 10a and 10b are separated by sawing along scribe line 20, the rotated hexagonal test pad 330 of FIG. 3B is more completely removed, therefore, the amount of test pad residue remaining in front of the seal ring 12a, 12b of each die 10a, 10b is further reduced. This in turn, further reduces the probability of pad peel-back and the die core cracking and damage associated therewith.

FIG. 4 shows a plan view of a fourth embodiment of the test pad 430 of the invention. The test pad 430 of the fourth embodiment has been modified to have an octagonal shape. The octagonal test pad 430 of the invention may be oriented within the illustrative 72 um wide scribe line 20 such that opposing edges 432a and 432b of the test pad are aligned to and parallel with the first and second seal rings 12a and 12b. In this illustrative embodiment (assuming a 72 um wide scribe line) the test pad 430 may have a side-to-side width W₄ of 70 um. The opposing edges 432a and 432b of the octagonal shape test pad 430 are shorter in length than the conventional test pad 30 of FIG. 1A, when their widths W₄ and W₀ are the same, thus providing a reduction in the amount of pad residue remaining in front of the seal ring 12a, 12b of each die 10a, 10b after dicing. As in the previous embodiments of the invention, the octagonal test pad 430 reduces the probability of pad peel-back and the die core cracking and damage associated therewith.

The test pad shapes and angular orientations described above are merely exemplary and other test pad shapes and angular orientations are contemplated that minimize the test pad residue remaining in front of the seal rings after dicing. For example, the test pad may comprise other polygonal shapes including, without limitation, rectangular, circular, and elliptical. The test pad may also comprise an irregular shape. The test pad may be rotated or oriented at an angle other than 45 degrees. For example, the test pad may be rotated at an angle of 30 or 40.5 degrees. In typical embodiments, the test pad of the invention will be rotated or oriented at angle ranging between about 5 degrees and about 45 degrees.

FIG. 1C shows a cross-sectional view of the conventional test pad 30. As shown, a plurality of metal layers 50, 51, 52 (only the uppermost metal layers in metal levels M6-M8 are shown for the purpose of clarity only) are formed over a wafer or substrate (neither one shown). The metal layers 50, 51, 52 are separated by an inter-metal dielectric 60, which may include alternating FSG and SiN layers. A passivation layer 70 is formed over the top metal layer 52. The passivation layer 70 may formed by a lower SiN layer 72, an intermediate PEOX layer 74 and an upper PESiN layer 76. Although not shown, the passivation layer 70 may also be formed as a single PESiN layer. The test pad 30 is disposed in an opening 80 formed above the uppermost metal layer 52 in the passivation layer 70. The opening 80 is sized to be within the edges of metal layer 52.

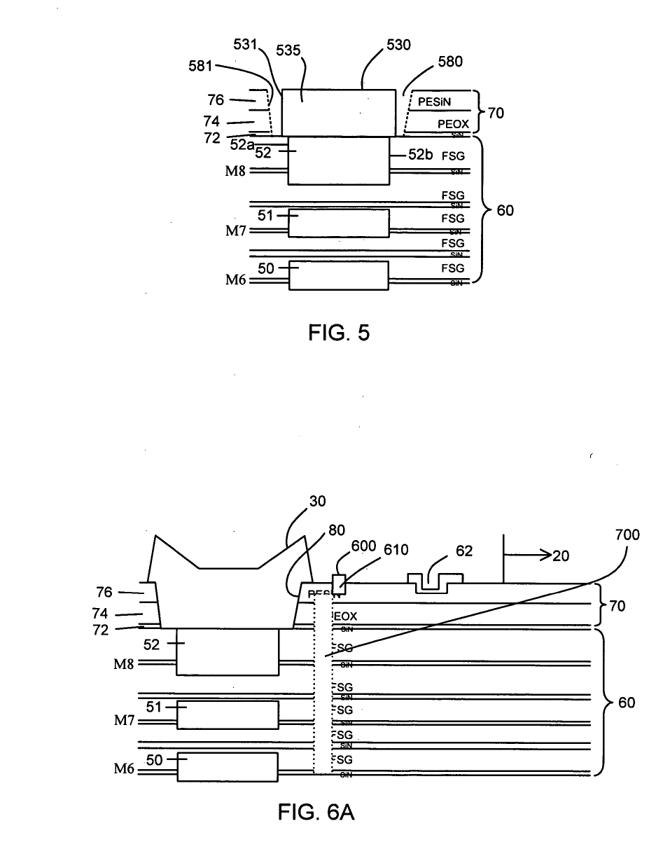

FIG. 5 shows a cross-sectional view of a fifth embodiment of the test pad 530 of the invention. As shown in FIG. 5, a plurality of metal layers 50, 51, 52 are formed over a wafer or substrate (neither one shown). The metal layers 50, 51, 52 are separated by an inter-metal dielectric 60, which may include alternating FSG and SiN layers. A passivation layer 70 is formed over the top metal layer 52 which may be formed by a lower SiN layer 72, an intermediate PEOX layer 74 and an upper PESiN layer 76, or alternatively, as a single PESiN layer.

The test pad 530 is disposed in an opening 580 formed above the uppermost metal layer 52 in the passivation layer 70. The opening 580 is sized to extend beyond the edges 52a, 52b of uppermost metal layer 52, instead of being within the edges 52a, 52b as in the conventional test pad design shown in the cross-sectional view of FIG. 1C.

The opening 580 is filled with a layer 535 of metal, such as aluminum, which forms the test pad 530. The metal layer 535 is deposited in the opening 580 such that a small gap is maintained between the side wall(s) 531 of the test pad 530 and the side wall(s) 581 of the opening 580 in the passivation layer 70 to create a “link-free” test pad that does not contact, extend above, or overlap the passivation layer 70, as does the conventional test pad 30 of FIG. 1C. The link-free test pad 530 of the invention prevents cracks from propagating through the passivation layer into the core of the wafer die or substrate after dicing.

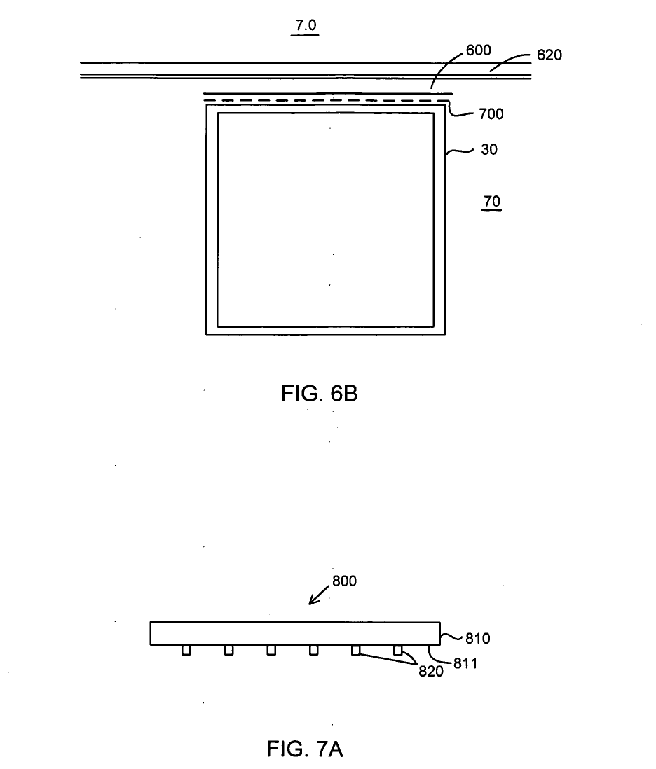

Another aspect of the invention is a protection structure for preventing cracks from propagating to the core of a wafer die or substrate after dicing. Referring to FIG. 6A, there is shown a cross-sectional view depicting first and second embodiments of the protection structure of the invention. As shown in FIG. 6A, a plurality of metal layers 50, 51, 52 are formed over a wafer or substrate. The metal layers 50, 51, 52 are separated by an inter-metal dielectric 60, which may include alternating FSG and SiN layers. A passivation layer 70 is formed over the top metal layer 52, the passivation layer 70 being formed, for example, by a lower SiN layer 72, an intermediate PEOX layer 74 and an upper PESiN layer 76. A test pad 30, e.g., WAT pad, is disposed in an opening 80 formed above the uppermost metal layer 52 in the passivation layer 70. In this embodiment, the test pad 30 is not within the boundaries of scribe line 20 (only one boundary is shown).

The protection structure embodied in FIG. 6A comprises an isolation trench 600 formed in the passivation layer 70 between the test pad 30 and an adjacent seal ring 620. The isolation trench 600 may be formed using conventional etching techniques. Preferably, the isolation trench 600 is located closer to the test pad 30 than the seal ring 620.

As shown in the plan view of FIG. 6B, the isolation trench 600 may extend parallel to its associated seal ring 620, and has a length that depends upon a number of factors including, without limitation, the length of the test pad(s) 30, the die size, the number of test pads associated with the trench, etc. In one embodiment, an isolation trench may be provided for each test pad. In such an embodiment, the predetermined length of each isolation trench may be approximately equal to or slightly greater than the length of its associated test pad. In another embodiment, a single, continuous isolation trench may be provided for two or more test pads. In such an embodiment, the predetermined length of the single, continuous isolation trench may be approximately equal to or slightly greater than the length of all associated test pads including the spaces therebetween.

In the embodiment shown in FIG. 6A, the isolation trench extends partially into the PESiN layer 76 a predetermined depth, typically about 0.1 um to about 5 um, depending upon the design of the fabrication process. In alternative embodiment, the isolation trench 600 may extend further into the PESiN layer 76, or all the way through the PESiN layer 76 into the other layer or layers of the passivation layer 70. In still another embodiment, the isolation trench 600 may extend entirely through the passivation layer 70 into the inter-metal dielectric 60.

In all embodiments, the isolation trench 600 may be filled with an oxide or nitride 610 so that it extends above the surface of the passivation layer 70 (PESiN layer 76). In one embodiment, oxide or nitride filled trench may extend above the surface of the passivation layer 70 about 0.01 um to about 5 um, depending upon the process design of the top metal thickness.

The isolation trench 600 operates as a barrier to block cracks originating due to residual test pad material that peels-pack after dicing. Accordingly, cracks are prevented from propagating into the passivation layer 70-after dicing.

Referring still to FIG. 6A, the protection structure may additionally comprise a crack stop layer 700 that starts just under the top surface of the passivation layer 70 and extends substantially vertically through the uppermost portion of the inter-metal dielectric 60. In one embodiment, the crack stop layer 700 may connect with the isolation trench 600.

Referring again to the plan view of FIG. 6B, the crack stop layer 700 is disposed between the test pad 30 and an adjacent seal ring 620 and extends parallel to the seal ring 620. Preferably, the crack stop layer 700 is positioned closer to the test pad 30 than the seal ring 620. Similar to the isolation trench 600, the crack stop layer 700 has a length that depends upon a number of factors including, without limitation, the length of the test pad(s) 30, the die size, the number of test pads associated with the crack stop layer, etc. In one embodiment, a crack stop layer may be provided for each test pad. In such an embodiment, the predetermined length of each crack stop layer may be approximately equal to or slightly greater than the length of its associated test pad. In another embodiment, a single, continuous crack stop layer may be provided for two or more test pads. In such an embodiment, the predetermined length of the single, continuous crack stop layer may be approximately equal to or slightly greater than the length of all associated test pads including the spaces therebetween.

The crack stop layer 700 may be formed prior to the PESiN layer 76 by etching a trench in the inter-metal dielectric 60 and filling the trench with an oxide or nitride. Once completed, the PESiN layer 76 may be formed over the crack stop layer 700.

The crack stop layer 700 also operates as a barrier to block cracks originating due to residual test pad material that peels-pack after dicing. Accordingly, cracks are prevented from propagating into the passivation layer 70 after dicing. Although shown in combination with the isolation trench 600, the crack stop layer 700 may be used alone without the isolation trench 600 if desired. In addition, either one or both of the protection structures may be used in combination with any of the earlier described test pads.

Another aspect of the invention is a probe card for performing electrical confirmation testing (wafer acceptance testing) of the semiconductor integrated circuits, via size reduced test pads. The probe card of the invention may also be used for testing displays of display devices, for operationally testing electronic circuit boards, and other such tests for semiconductor integrated circuits, and for performing circuit adjustments. The probe card comprises a plurality of probe pins extending from the probe substrate in a manner which causes free ends of the pins to contact the test pads of the wafer, substantially across the maximum dimension of each of the pads.

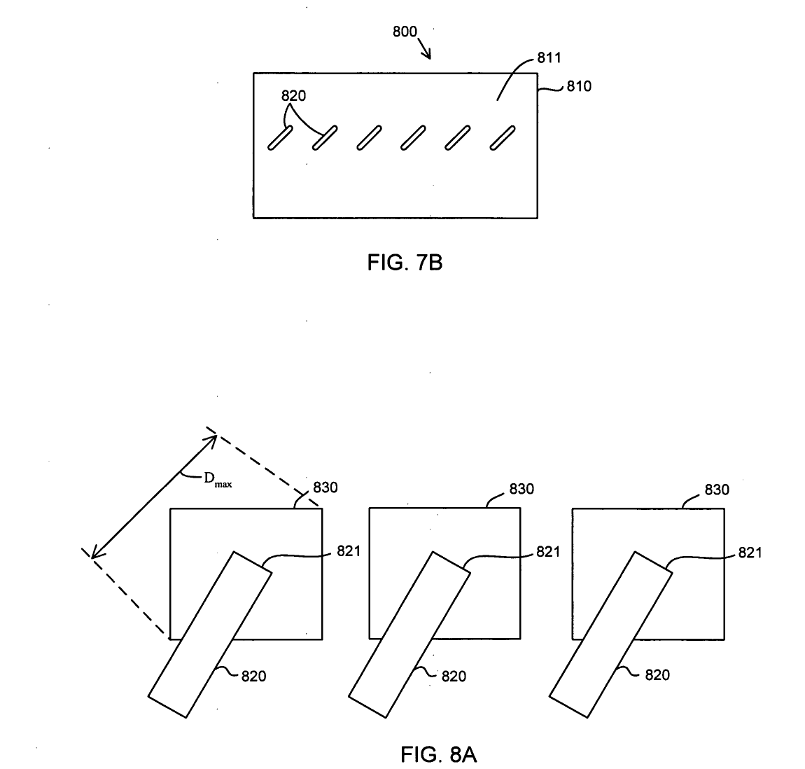

FIGS. 7A and 7B are elevational and plan views, respectively, of a probe card according to an embodiment of the invention, denoted by numeral 800. The probe card 800 comprises a probe substrate 810 such as a circuit board, and a plurality of probe pins 820 extending from a bottom surface 811 of the probe substrate 810. The probe card 800 applies and receives electrical signals to and from test pads, e.g., WAT pads, via the probe pins 820 and the probe substrate 810, and may be connected to a testing apparatus (not shown) so that the test results can be recorded, displayed, etc. The probe card 800 may be configured to apply electrical currents for adjusting semiconductor integrated circuits.

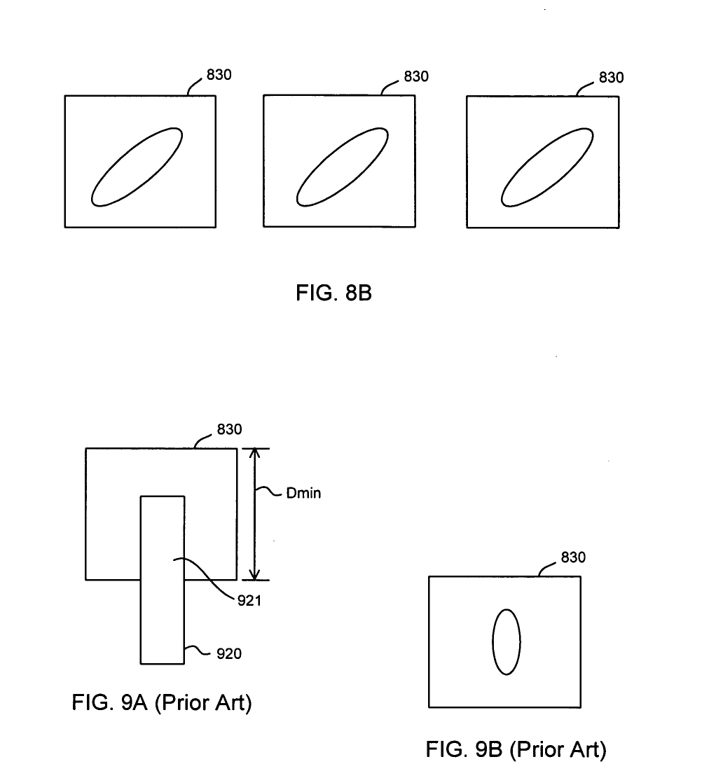

As shown in the plan view of FIG. 8A, the probe pins 820 extend from the substrate 810 in a manner which allows the free ends or tips 821 of the probe pins 820 to contact test pads of the wafer substantially across the maximum dimension Dₘₐₓ of each of the pads 830 where the contact area is the greatest. In contrast, FIG. 9A shows that the tips 921 of the probe pins 920 of a prior art probe card are arranged to contact a test pad across its minimum dimension Dₘᵢₙ.

The greater surface area available across the maximum dimension Dₘₐₓ of the test pads 830 ensures proper contact between the tips 820 of the probe pins 820 and the test pads 830. FIG. 8B depicts the probe pin marks 850 that are made on the test pads 830 by the probe pins 820 of the probe card 800 of the invention. FIG. 9B depicts the probe pin mark 950 that is made on test pad 830 by a probe pin 920 of a conventional probe card. As can be seen by comparing FIGS. 8B and 9B, the probe pin marks 850 made by the probe card of the invention are larger than the probe pin marks 950 made by a prior art probe card because more surface area is available across the maximum dimension Dₘₐₓ of the test pads 830 for the probe pins 820 to slide.

In the shown embodiment of FIG. 7B, the probe pins 820 may extend from the substrate 810 in an oblique manner, which allows the free ends or tips of the probe pins 820 contact the conventional test pads shown in FIG. 1A or the test pads of the invention shown in FIGS. 3A and 4, substantially across the maximum dimension of each of the pads where contact area is the greatest. The probe pins may also be constructed to extend in a non-oblique manner to contact the test pads of the invention shown in FIGS. 2A and 3B, which have been rotated 45 degrees.

While the foregoing invention has been described with reference to the above, various modifications and changes can be made without departing from the spirit of the invention. Accordingly, all such modifications and changes are considered to be within the scope of the appended claims.

What is claimed is:

1. A probe card comprising:
a member for sending and receiving electrical signals for operational testing of a semiconductor integrated circuit having a plurality of test pads each having a maximum dimension; and
a plurality of probe pins extending from the member in a manner which causes free ends of the pins to contact the test pads substantially across the maximum dimension of the pads.

2. The probe card according to claim 1, wherein the plurality of probe pins, when the probe card is viewed in plan, extend from the member in an inclined manner.

3. A test pad for a wafer or a substrate, the test pad comprising a pad of electrically conductive material disposed in an area between seal rings of the wafer or substrate, the pad having a rotational orientation within the area between the seal rings that minimizes pad material immediately adjacent the seal rings.

4. The test pad of claim 3, wherein the pad has a shape that further minimizes the pad material immediately adjacent the seal rings.

5. The test pad of claim 4, wherein the shape is a polygon.

6. The test pad of claim 3, wherein the shape is a polygon selected from the group consisting of square, rectangular, hexagonal, octagonal, circular, and elliptical.

7. The test pad of claim 3, where the shape is irregular.

8. The test pad of claim 3, wherein the rotational orientation is an angle between about 5 degrees to about 45 degrees.

9. The test pad of claim 3, wherein the area between the seal rings forms a scribe line.

10. A test pad for a wafer or a substrate, the test pad comprising a pad of electrically conductive material disposed in an area between seal rings of the wafer or substrate, the pad having a shape that minimizes pad material immediately adjacent the seal rings.

11. The test pad of claim 10, wherein the shape is a polygon.

12. The test pad of claim 10, wherein the shape is a polygon selected from the group consisting of square, rectangular, hexagonal, octagonal, circular, and elliptical.

13. The test pad of claim 3, where the shape is irregular.

14. A test pad for a wafer or substrate having a passivation layer disposed thereover, the passivation layer including an opening disposed over an uppermost metal layer, the test pad comprising:
a layer of electrically conductive material disposed in the opening over the uppermost metal layer;
wherein the opening and the layer of electrically conductive material are dimensioned so that the layer of conductive material does not contact the passivation layer.

15. The test pad of claim 14, wherein the test pad is formed on a scribe line.

16. The test pad of claim 14, wherein a sidewall of the opening does not contact an adjacent sidewall of the layer of electrically conductive material.

17. The test pad of claim 14, wherein the layer of electrically conductive material does not overlap a top surface of the passivation layer.

18. The test pad of claim 14, wherein the layer of electrically conductive material does not extend above a top surface of the passivation layer.

19. The test pad of claim 14, wherein the test pad comprises a wafer acceptance testing pad.

20. The test pad of claim 14, wherein the test pad is disposed in an area between seal rings of the wafer or substrate, the pad having at least one of a shape and a rotational orientation within the area between the seal rings that minimizes pad material immediately adjacent the seal rings.

21. A protection structure for a wafer die core comprising:
a wafer including a passivation layer and a test pad extending through the passivation layer; and
a trench in the passivation layer adjacent to an edge of the test pad.

22. The protection structure according to claim 21, wherein the trench is filled with an oxide.

23. The protection structure according to claim 21, wherein the trench is filled with a nitride.

24. The protection structure according to claim 21, wherein the trench extends parallel to a seal ring of the wafer.

25. The protection structure according to claim 24, wherein the trench is between the test pad and the seal ring.

26. The protection structure according to claim 21, wherein the trench is filled with an oxide and the oxide extends above a top surface of the passivation layer.

27. The protection structure according to claim 21, wherein the trench is filled with a nitride and the nitride extends above a top surface of the passivation layer.

28. The protection structure according to claim 21, wherein the trench extends down into at least a portion of an inter-metal dielectric.

29. The protection structure according to claim 28, wherein the trench is filled with an oxide.

30. The protection structure according to claim 28, wherein the trench is filled with a nitride.

31. The protection structure according to claim 21, wherein the test pad is disposed in a scribe line.

32. The protection structure according to claim 21, further comprising another trench in the passivation layer adjacent to an edge of the test pad, one of the trenches filled with an oxide or a nitride and extending above a top surface of the passivation layer and the other one of the trenches filled with an oxide or nitride and extending down into at least a portion of an inter-metal dielectric.

33. The protection structure of claim 32, wherein the test pad is disposed in an area between seal rings of the wafer or substrate, the pad having at least one of a shape and a rotational orientation within the area between the seal rings that minimizes pad material immediately adjacent the seal rings.

34. The protection structure of claim 33, wherein the test pad extends through an opening in the passivation layer, the opening disposed over an uppermost metal layer, the opening and the test pad dimensioned so that the test pad does not contact the passivation layer.

35. The protection structure of claim 21, wherein the test pad extends through an opening in the passivation layer, the opening disposed over an uppermost metal layer, the opening and the test pad dimensioned so that the test pad does not contact the passivation layer.

36. The protection structure of claim 21, wherein the test pad is disposed in an area between seal rings of the wafer or substrate, the pad having at least one of a shape and a rotational orientation within the area between the seal rings that minimizes pad material immediately adjacent the seal rings.

37. The protection structure of claim 36, wherein the test pad extends through an opening in the passivation layer, the opening disposed over an uppermost metal layer, the opening and the test pad dimensioned so that the test pad does not contact the passivation layer.
